(19) United States
(12) Patent Application Publication
(10) Pub. No.: US 2005/0006718 A1
(43) Pub. Date: Jan. 13, 2005

(54) Semiconductor device

(75) Inventors: Hikoshi Hanji, Hyogo (JP); Yasuhiro Matsui, Hyogo (JP)

Correspondence Address: McDermott, Will & Emery, 600 13th Street, N.W., Washington, DC, 20005-3096, US

(73) Assignee: Renesas Technology Corp.

(21) Appl. No.: 10/886,580

(22) Filed: Jul. 9, 2004

(30) Foreign Application Priority Data
Jul. 10, 2003 (JP) 2003-195021(P)

(51) Int. Cl. H01L 29/00

(52) U.S. Cl. 257/529

(57) ABSTRACT

A semiconductor device includes a fuse wire, a portion to be fused that overlies the fuse wire with an insulation film interposed therebetween, and a plug connecting the portion to be fused and the fuse wire together. The portion to be fused underlies an insulation film having a thickness, and the fuse wire underlies an insulation film having a thickness larger than that of the insulation film overlying the portion to be fused. The insulation film overlying the fuse wire has a thickness sufficient to prevent a laser beam from blowing the fuse wire.

### BACKGROUND OF THE INVENTION

1. Field of the Invention

The present invention relates generally to semiconductor devices and particularly to semiconductor devices having a portion to be fused.

2. Description of the Background Art

A conventional semiconductor device having a fuse arrangement is disclosed for example in Japanese Patent Laying-Open No. 7-273200.

The publication discloses a technique employed to repair a defect of a circuit pattern of a semiconductor memory. More specifically, a chip is internally provided with spare memory cells (a redundant circuit) and if it is found before shipment that a regular memory cell is defective, a prescribed fuse is blown by a laser beam to disconnect the defective memory cell from a line while a spare memory cell is rendered effective. Furthermore the publication also discloses that if the fuse employed in this method is microfabricated and such fuses are arranged at reduced intervals, an insulation film and other regions excluding that at which the fuse is blown can minimally be damaged and adjacent fuses can also be prevented from being blown. More specifically, the publication discloses a semiconductor device having a plurality of fuses arranged in parallel and covered with a reflector that is formed for example of aluminum capable of reflecting a beam emitted to blow a fuse and having a plurality of beam irradiation windows corresponding to the fuses, respectively, and each offset from adjacent windows as seen in the fuses' longitudinal direction.

The semiconductor device as described above, however, has a disadvantage as described hereinafter.

When a fuse is blown by a laser beam, the laser beam instantly heats the fuse and thus blows it together with an oxide film (an insulation film) explosively, and the explosion can give an impact damaging a portion that should not be blown, such as a fuse wire, an insulation film, and the like.

While the publication discloses introducing a reflector to minimize damage to the oxide film, the publication fails to disclose that a portion of a fuse that is to be blown is spaced from the fuse wire by a large distance so that the wire is less affected by blowout.

Furthermore, as seen from a point of view different than the above, the reflector having beam irradiation windows as described in the publication is disadvantageous as it is fabricated by a time consuming and hence inefficient process.

### SUMMARY OF THE INVENTION

The present invention has been made to overcome such disadvantage as described above and it contemplates a semiconductor device having a fuse wire less affected by blowout.

The present semiconductor device includes a fuse wire, a portion of a fuse that is to be blown, overlying the fuse wire with an insulation film interposed therebetween, and an interconnect portion connecting the fuse wire and the portion of the fuse that is to be blown. The portion of the fuse that is to be blown (the portion to be fused) and the fuse wire are formed of identical material, and the portion to be fused is smaller in area than the fuse wire in cross section as seen in a direction perpendicularly across the fuse wire.

In accordance with the present invention the semiconductor device can have a fuse blown by a laser beam while preventing the blowout by the laser beam from significantly damaging an adjacent fuse wire.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a plan view of a fuse arrangement in a semiconductor device of the present invention in a first embodiment.

FIGS. 2 and 3 are cross sections of the FIG. 1 fuse arrangement taken along lines II-II and III-III, respectively.

FIG. 4 is a plan view of a fuse arrangement in the present semiconductor device in a second embodiment.

FIGS. 5 and 6 are cross sections of the FIG. 4 fuse arrangement taken along lines V-V and VI-VI, respectively.

FIG. 7 is a cross section of a fuse arrangement in the present semiconductor device in a third embodiment.

### DESCRIPTION OF THE PREFERRED EMBODIMENTS

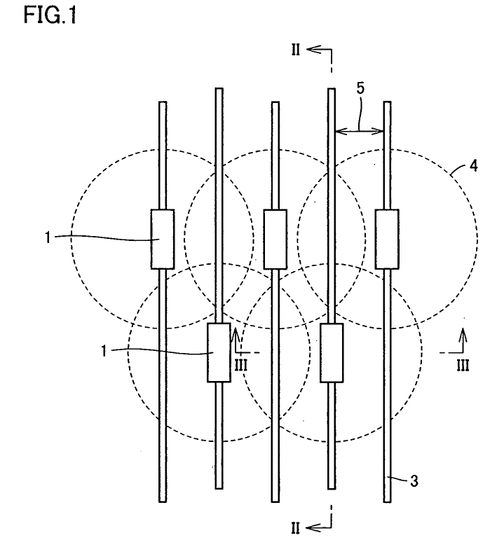

Hereinafter in accordance with the present invention a semiconductor device in embodiments will be described with reference to FIGS. 1-7.

### First Embodiment

The semiconductor device includes a memory cell array having a plurality of memory cells covered with an insulating protection film. The memory cell array is adjacent to a peripheral circuitry portion having peripheral circuitry formed therein to control the memory cells' operation. The peripheral circuitry portion is provided with a fuse disconnecting a defective memory cell from a line to replace the defective memory cell with a spare memory cell.

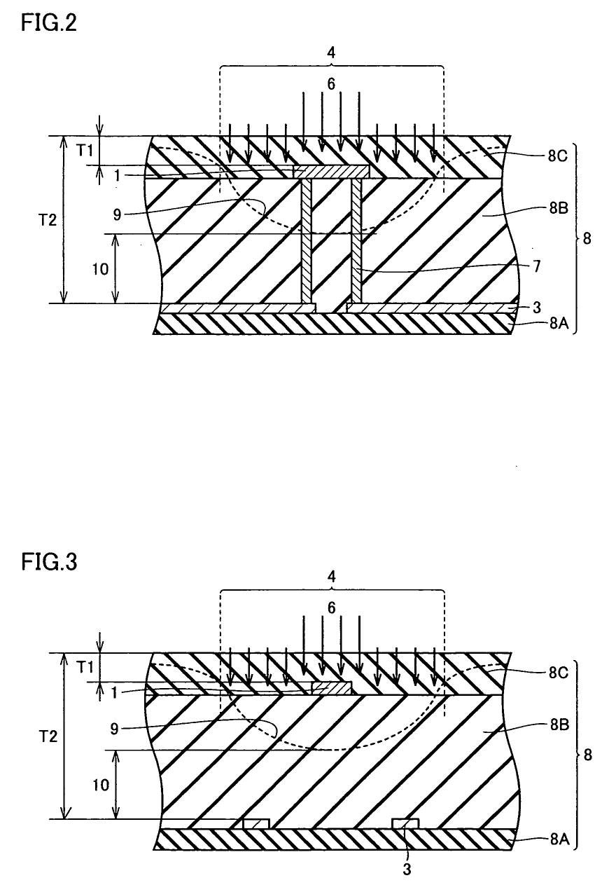

FIG. 1 is a plan view of a fuse portion of the semiconductor device in the first embodiment, and FIGS. 2 and 3 show the fuse portion as seen in cross section taken along lines II-II and III-III, respectively, of FIG. 1.

In the present embodiment the semiconductor device, as shown in FIGS. 1-3, includes a fuse wire 3 arranged on an insulation film 8A, a portion to be fused 1 arranged over fuse wire 3 with an insulation film 8B interposed therebetween, and a plug 7 serving as an interconnect portion connecting fuse wire 3 and the portion to be fused 1. Furthermore on insulation film 8B an insulation film 8C is deposited to cover the portion to be fused 1. The portion to be fused 1 is fused by a laser beam 6 directed toward fuse wire 3, as indicated in FIGS. 2 and 3 by arrows.

The portion to be fused 1 is formed for example of polycrystalline silicon, aluminium alloy or a similar material readily fusible by laser beam 6. Plug 7 is formed for example of tungsten.

Furthermore, the portion to be fused 1 is staggered, as shown in FIG. 1, so that when a portion to be fused is fused a different portion to be fused is not included in a laser beam irradiation range 4. This allows a wire to be blown, while a different, adjacent wire's portion to be fused is not damaged. Furthermore, the portion to be fused 1 staggered can contribute to a reduced inter-wire pitch 5.

Note that the portion to be fused 1 may be arranged, as seen in plane, in a manner other than the staggering manner as described above. For example, if fuse wires have their respective portions to be fused arranged obliquely to prevent the portions from overlapping as seen in the fuse wires' longitudinal direction, inter-wire pitch 5 can be smaller than when the portions are staggered.

Insulation film 8 (8A-8C) for example contains oxide film (SiO2) and is formed for example by chemical vapor deposition (CVD).

Note that the above described fuse is provided to repair a defect in a memory cell array of a semiconductor device. When a defective cell is detected, the portion to be fused 1 is blown to assign to a redundant cell an address corresponding to the defective cell.

When the above described fuse has the portion to be fused 1 exposed to a laser beam and thus fused, insulation film 8 upper than a damage line 9 (see FIGS. 2 and 3) is blown off as it is instantly heated in fusing the portion. (The fuse is blown out.) As a result, insulation film 8 lower than damage line 9 will have therein fuse wire 3 and a portion of plug 7 that remains. Note that damage line 9 generally has a Gaussian curve, as shown in FIGS. 2 and 3.

In general, laser beam irradiation range 4 has an area across a plurality of fuse wires, as shown in FIG. 1, and as it is instantly heated, as described above, fuse wire adjacent to a fuse to be blown may also be damaged.

A conventional semiconductor device addresses this problem by increasing inter-fuse pitch 5 to blow a portion to be fused without damaging a different portion to be fused. Inter-fuse pitch 5 thus increased, however, is an obstacle to miniaturizing the semiconductor device.

By contrast, the semiconductor device in the present embodiment includes a portion to be fused that has a frame structure or a structure having a vertically standing portion connecting by plug 7 the portion to be fused 1 and fuse wire 3 arranged in different layers. Insulation film 8 located on the portion to be fused 1 has a thickness (T1) and insulation film 8 located on fuse wire 3 has a thickness (T2) larger than thickness T1, and sufficient to prevent a laser beam from blowing out fuse wire 3.

This ensures that the portion to be fused 1 is blown while insulation film 8 remains in a margin region 10 so that a fuse wire that should be blown is fused while a fuse wire adjacent thereto can be free of damage.

FIG. 3 shows that fuse wire 3, formed for example of a material larger in heat resistance than the portion to be fused 1, has an area smaller as seen in cross section than the portion to be fused 1. If the portion to be fused 1 and fuse wire 3 are formed of identical material, it is preferable that the portion to be fused 1 has an area smaller as seen in cross section than fuse wire 3. Fuse wire 3 has an area, as seen in cross section, sufficient to prevent a laser beam from blowing the wire.

While a fuse wire that should be blown is fused, a fuse wire adjacent thereto can be free of damage.

Note that an “area as seen in cross section” is herein that of a single portion to be fused or that of a single fuse wire as seen in cross section in a direction perpendicular to a direction in which fuse wire 3 extends (i.e., as seen in cross section in the direction shown in FIG. 3).

Fuse wire 3 and the portion to be fused 1 are formed by a process as described hereinafter.

On insulation film 8A (a first insulation film) fuse wire 3 as prescribed is deposited and thereon insulation film 8B (a second insulation film) is deposited. Subsequently, insulation film 8B is provided with a contact hole reaching fuse wire 3 and in the contact hole plug 7 is formed. Subsequently on insulation film 8B and plug 7 the portion to be fused 1 as prescribed is deposited and furthermore on insulation film 8B and the portion to be fused 1 insulation film 8C (a third insulation film) is deposited.

On fuse wire 3, insulation film 8 has a thickness (indicated in FIGS. 2 and 3 by T2) determined as appropriate by a quantity of energy directed, a distance from an adjacent fuse, laser beam irradiation ranges that overlap, and the like. Thickness T2 is for example approximately not less than 15 μm and not more than 20 μm for example when a laser beam irradiation range has a diameter of 5 μm, the portion to be fused is formed of polycrystalline silicon, the fuse wire is formed of rhodium compound, the portion to be fused has an area of 2.0 μm² as seen in cross section, the fuse wire has an area of 1.0 μm² as seen in cross section, fuse wires are arranged with a pitch of 3.0 μm, and plug 7 has a height of 10 μm. On the portion to be fused 1, insulation film 8 has a thickness (indicated in FIGS. 2 and 3 by T1) for example of approximately not less than 3 μm and not more than 5 μm.

Insulation film 8 may contain spin on glass (SOG) and may be deposited by centrifugal force, or it may be sputtered while high density plasma (HDP) is used to cause plasma excitation to deposit the film. When higher heat resistance to laser beam is considered, however, it is preferable that insulation film 8 include a high-density insulation oxide film, a film formed by HDP.

The oxide film formed by HDP has a composite crystal lattice, a crystal lattice close to amorphous state, having molecules bonded together by a large strength, exhibiting high heat resistance to laser beam. Thus fuse wire 3 can be prevented from having damage while insulation film 8 can further be reduced in thickness.

### Second Embodiment

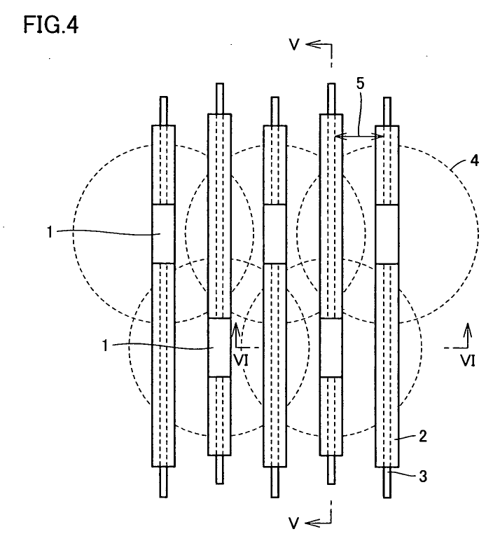

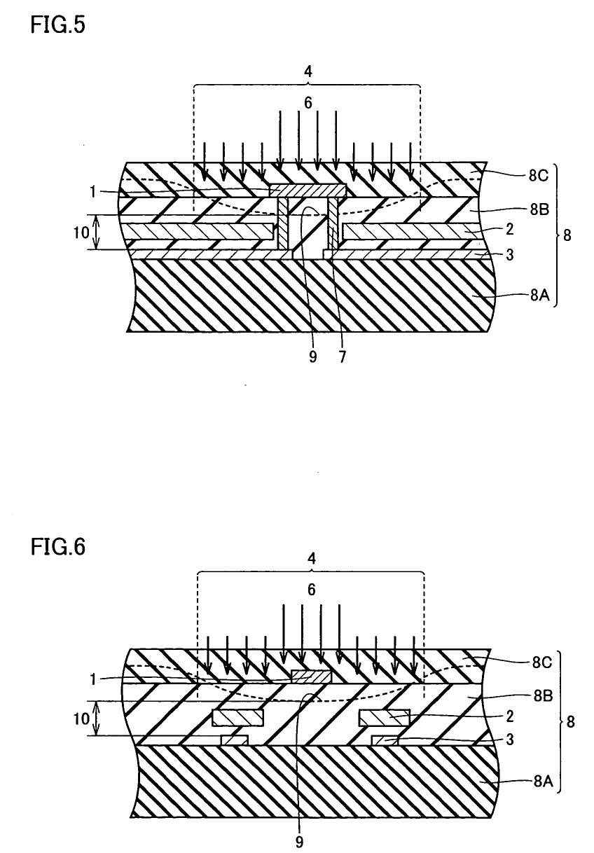

FIG. 4 is a plan view of a fuse portion of the semiconductor device in a second embodiment, and FIGS. 5 and 6 show cross sections taken along lines V-V and VI-VI, respectively, of FIG. 4.

The present embodiment provides a semiconductor device corresponding to that of the first embodiment in a variation by way of example. As shown in FIGS. 4-6, over fuse wire 3 (upstream as seen in a direction in which a laser beam is directed (as indicated in FIGS. 5 and 6 by arrows)) an intermediate layer 2 is introduced to serve as an energy absorption layer that absorbs laser beam.

Note that if intermediate layer 2 is formed of conductive material, intermediate layer 2 is arranged on fuse wire 3 with an oxide film interposed therebetween that has a thickness (of approximately not less than 1 μm to not more than 2 μm) to ensure insulation.

Such an intermediate layer 2 can absorb an incident laser beam's energy to reduce damage to adjacent fuse wire 3.

The energy absorption layer can be formed of optically absorptive material such as polycrystalline silicon.

In this example, intermediate layer 2 having a width approximately not less than twice and not more than three times that of fuse wire 3 and a thickness of approximately not less than twice and not more than ten times (more preferably, approximately not less than twice and not more than five times) that of fuse wire 3, can absorb laser beam's energy to prevent blowout of fuse wire 3.

Other than polycrystalline silicon, intermediate layer 2 can be formed of tin and thin alloy, black rhodium and black chromium, a compound thereof, and the like to allow the layer to have a smaller area in cross section to still absorb large energy.

Furthermore, intermediate layer 2 may be formed to be a laser beam reflecting layer, or the energy absorption layer and the laser beam reflecting layer may both be introduced. If the energy absorption layer and the laser beam reflecting layer are both be introduced, it is preferable that the energy absorption layer underlie the laser beam reflecting layer, although the laser beam reflecting layer may underlie the energy absorption layer.

The laser beam reflecting layer can reflect an incident laser beam to reduce damage to adjacent fuse wire 3.

The laser beam reflecting layer can be formed of material including chromium, gold, gold alloy, rhodium, nickel, aluminum, a compound thereof, or a similar, highly optically reflective material.

The laser beam reflecting layer reflects an emitted laser beam to prevent blowout of fuse wire 3.

Preferably, fuse wire 3 is higher in heat resistance than the portion to be fused 1. Accordingly, fuse wire 3 preferably contains a material higher in heat resistance than the portion to be fused 1 and infusible against laser beam radiation as described above. Such material includes copper, rhodium, palladium, platinum, silver, a compound thereof, and the like.

This allows a reduced thickness of margin region 10 of insulation film 8 protecting adjacent fuse wire 3 in fusing, and insulation film 8 can be deposited by a simplified process.

Note that components, features and the like of the present embodiment that are similar to those of the first embodiment will not be described in detail.

### Third Embodiment

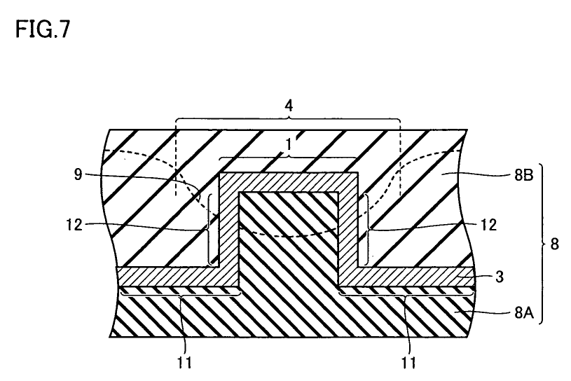

FIG. 7 is a cross section of a fuse portion of the semiconductor device in a third embodiment.

The present embodiment provides a semiconductor device corresponding to those of the first and second embodiments in a variation by way of example. It is different in that the portion to be fused 1, and fuse wire 3 including a wire portion 11 and an interconnect portion 12 are formed by an integral conductive layer to allow the portion to be fused to be formed by a simple process.

The conductive layer can be formed of a material similar to those described in the first and second embodiments (e.g., polycrystalline silicon, Al alloy).

The portion to be fused 1 and fuse wire 3 as described above are formed by a process as will be described hereinafter.

On insulation film 8A (a first insulation film) a trench is formed and thereon CVD or sputtering is employed to deposit the conductive layer. On the conductive layer insulation film 8B (a second insulation film) is deposited to obtain a structure as shown in FIG. 7.

Note that components, features and the like of the present embodiment that are similar to those of the first and second embodiments will not be described in detail.

Features of the semiconductor devices as described in the above embodiments can be combined as appropriate.

Although the present invention has been described and illustrated in detail, it is clearly understood that the same is by way of illustration and example only and is not to be taken by way of limitation, the spirit and scope of the present invention being limited only by the terms of the appended claims.

1. A semiconductor device comprising:
a fuse wire;
a portion to be fused, overlying said fuse wire with an insulation film interposed therebetween; and
an interconnect portion connecting said fuse wire and said portion to be fused together, wherein
said portion to be fused and said fuse wire are formed of identical material, and said portion to be fused is smaller in area than said fuse wire in cross section as seen in a direction perpendicularly across said fuse wire.

2. A semiconductor device comprising:
a fuse wire;
a portion to be fused, overlying said fuse wire with an insulation film interposed therebetween; and
an interconnect portion connecting said fuse wire and said portion to be fused together, wherein
said insulation film includes an oxide film formed by high density plasma.

3. A semiconductor device comprising:
a fuse wire;
a portion to be fused, overlying said fuse wire with an insulation film interposed therebetween; and
an interconnect portion connecting said fuse wire and said portion to be fused together, wherein
said fuse wire underlies an energy absorption layer absorbing a laser beam.

4. A semiconductor device comprising:
a fuse wire;
a portion to be fused, overlying said fuse wire with an insulation film interposed therebetween; and
an interconnect portion connecting said fuse wire and said portion to be fused together, wherein
said fuse wire underlies a laser beam reflecting layer reflecting a laser beam.

5. A semiconductor device comprising:
a fuse wire;
a portion to be fused, overlying said fuse wire with an insulation film interposed therebetween; and
an interconnect portion connecting said fuse wire and said portion to be fused together, wherein
said fuse wire is higher in heat resistance than said portion to be fused.

6. A semiconductor device comprising:
a fuse wire;
a portion to be fused, overlying said fuse wire with an insulation film interposed therebetween; and
an interconnect portion connecting said fuse wire and said portion to be fused together, wherein
said fuse wire, said portion to be fused and said interconnect portion are formed of an integral conductive layer.

7. A semiconductor device comprising:
a fuse wire; and
a portion to be fused, overlying said fuse wire and located internal to an insulation film,
said insulation film overlying said portion to be fused being smaller in thickness than said insulation film overlying said fuse wire.

8. The semiconductor device of claim 7, wherein said portion to be fused and said fuse wire are formed of identical material, and said portion to be fused is smaller in area than said fuse wire in cross section as seen in a direction perpendicularly across said fuse wire.

9. The semiconductor device of claim 7, wherein said insulation film includes an oxide film formed by high density plasma.

10. The semiconductor device of claim 7, wherein said fuse wire underlies an energy absorption layer absorbing a laser beam.

11. The semiconductor device of claim 7, wherein said fuse wire underlies a laser beam reflecting layer reflecting a laser beam.

12. The semiconductor device of claim 7, wherein said fuse wire is higher in heat resistance than said portion to be fused.

13. The semiconductor device of claim 7, wherein said fuse wire and said portion to be fused are formed of an integral conductive layer.
